(19) United States
(12) Patent Application Publication
(10) Pub. No.: US 2026/0066850 A1
(43) Pub. Date: Mar. 5, 2026

(54) AMPLIFIER CIRCUIT AND METHOD FOR STABILIZING BIAS CURRENT OF AN AMPLIFIER CIRCUIT

(71) Applicant: RichWave Technology Corp., Taipei City (TW)

(72) Inventors: Tien-Yun Peng, Taipei City (TW); Chih-Sheng Chen, Taipei City (TW)

(73) Assignee: RichWave Technology Corp., Taipei City (TW)

(21) Appl. No.: 18/928,208

(22) Filed: Oct. 28, 2024

(30) Foreign Application Priority Data
Aug. 29, 2024 (TW) 113132582

(51) Int. Cl. H03F 1/02; H03F 3/193

(52) U.S. Cl. CPC H03F 1/0216; H03F 3/193; H03F 2200/451; H03F 2200/471; H03F 2200/504; H03F 2200/84

(57) ABSTRACT

An amplifier circuit includes an input terminal, an output terminal, a first transistor, a second transistor, a third transistor, and a voltage tracking circuit. The input terminal would receive an input signal. The output terminal would output the amplified input signal. The control terminals of the first transistor and the second transistor are coupled to one another. The voltage tracking circuit is coupled to a first terminal and the control terminal of the first transistor, a first terminal of the second transistor, and a first terminal of the third transistor. The voltage tracking circuit regulates voltages at the first terminal of the first transistor and the first terminal of the third transistor to be substantially equal during an initial state, and then regulates voltages at the first terminal of the first transistor and the first terminal of the second transistor to be substantially equal during a stable state.

### TECHNICAL FIELD

This disclosure relates to an amplifier circuit and a method related to the amplifier circuit, particularly, an amplifier circuit that can provide a bias voltage in a stable state and a method for stabilizing a bias current of the amplifier circuit.

### BACKGROUND

Current mirrors are fundamental components in analog circuits, widely used in bias circuits and amplifier stage loads of various circuits. Therefore, the precise mirroring characteristics of the current mirror are very important, and the stability and accuracy of its output current can determine the quality of the current mirror characteristics. The current mirror device can be formed using metal-oxide-semiconductor field effect transistors (MOSFETs) or bipolar junction transistors (BJTs). For example, when the drain bias voltage of the transistor is increased to enter the saturation region, the channel length shortens, making the relationship between the operating current and voltage in the saturation region not only related to the gate-source voltage (commonly referred to as VGS) of the transistor as in the ideal state, but also related to the drain-source voltage (commonly referred to as VDS) due to the channel length modulation effect. Therefore, the current mirror device is easily affected by the process and bias changes of the MOSFET, making it unable to accurately and stably mirror and generate the output current. When a current mirror is applied to amplifiers (e.g., power amplifiers, low-noise amplifiers, etc.), the current mirror can provide a current for the amplifier. However, unexpected oscillations often occur due to the instability of the circuit. Therefore, there is still a lack of suitable solutions in the field to address related problems.

### SUMMARY

An embodiment provides an amplifier circuit. The amplifier circuit can include an input terminal, an output terminal, a first transistor, a second transistor, a third transistor, and a voltage tracking circuit. The input terminal can be configured to receive an input signal. The output terminal can be configured to output an amplified input signal. The first transistor can include a first terminal configured to receive a first reference current, a second terminal coupled to a first bias terminal, and a control terminal. The second transistor can include a first terminal configured to receive a second reference current, a second terminal coupled to the first bias terminal, and a control terminal coupled to the input terminal and the control terminal of the first transistor. The third transistor can include a first terminal configured to receive a third reference current, a second terminal coupled to the first bias terminal, and a control terminal. The voltage tracking circuit can include a first input terminal coupled to the first terminal of the first transistor, a second input terminal coupled to the first terminal of the second transistor, a third input terminal coupled to the first terminal of the third transistor, and an output terminal coupled to the control terminal of the first transistor. The voltage tracking circuit is configured to regulate voltages at the first terminal of the first transistor and the first terminal of the third transistor to be substantially equal during an initial state, and to regulate voltages at the first terminal of the first transistor and the first terminal of the second transistor to be substantially equal after a predetermined time has elapsed.

Another embodiment provides a method for stabilizing a bias current of an amplifier circuit. The amplifier circuit can include an input terminal for receiving an input signal and an output terminal for outputting an amplified input signal. The method can include utilizing a first transistor to receive a first reference current; utilizing a second transistor to receive a second reference current, where a control terminal of the second transistor is coupled to the input terminal and a control terminal of the first transistor, and the first transistor and the second transistor are coupled to a first bias terminal; utilizing a third transistor to receive a third reference current; coupling a voltage tracking circuit to a first terminal of the first transistor for regulating voltages at the first terminal of the first transistor and the first terminal of the third transistor to be substantially equal during an initial state, and regulating voltages at the first terminal of the first transistor and the first terminal of the second transistor to be substantially equal after a predetermined time has elapsed; and coupling a first output terminal of the voltage tracking circuit to the control terminal of the first transistor.

### BRIEF DESCRIPTION OF THE DRAWINGS

FIG. 1 shows a diagram of an amplifier circuit according to an embodiment.

FIG. 2 shows a diagram of the operation of the amplifier circuits in the embodiment of FIG. 1 and FIG. 3 to FIG. 9.

FIG. 3 shows a diagram of an amplifier circuit according to another embodiment.

FIG. 4 shows a diagram of an amplifier circuit according to another embodiment.

FIG. 5 shows a diagram of an amplifier circuit according to another embodiment.

FIG. 6 shows a diagram of a voltage tracking circuit in FIG. 1 and FIG. 3 to FIG. 5.

FIG. 7 shows a diagram of an amplifier circuit according to another embodiment.

FIG. 8 shows a diagram of the amplifier circuit in FIG. 7 according to an embodiment.

FIG. 9 shows a flowchart of a bias current method for stabilizing the amplifier circuits in FIG. 1 to FIG. 7.

FIG. 10 shows a diagram of an amplifier circuit according to another embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In this document, when referring to the size of a transistor, the size of the transistor can be defined by the gate width of the transistor, the width/length ratio (W/L ratio, W to L), and/or the number of fingers, which together define the equivalent size of the transistor. In this document, when referring to two transistors corresponding to the same width/length ratio, one transistor may be formed with at least one first transistor unit, and the other transistor may be formed with at least one second transistor unit, and the first transistor unit and the second transistor unit may have the same width/length ratio. In this document, according to embodiments, when referring to two components being coupled to each other, they may be directly coupled or indirectly coupled via other components. The following describes circuits of embodiments with reference to the drawings, and reasonable modifications to the circuit described below are still within the scope of embodiments.

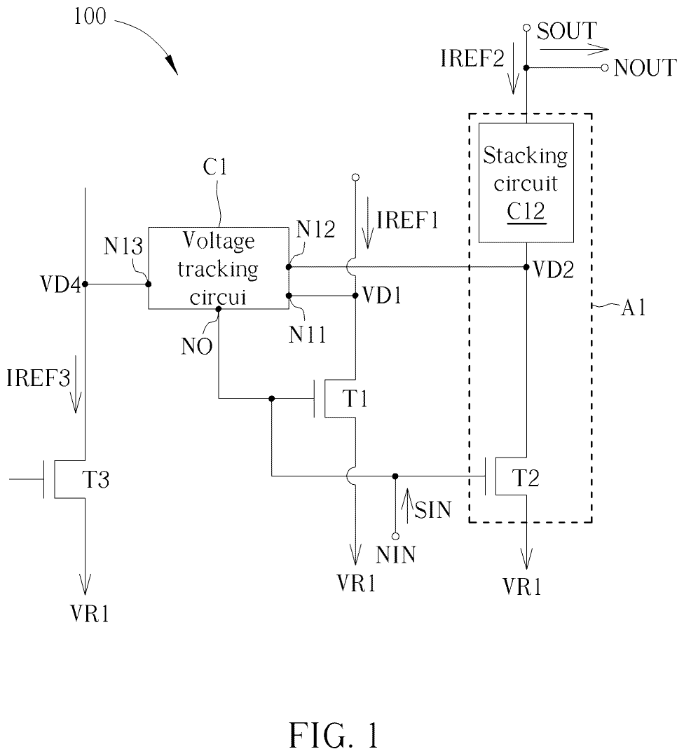

FIG. 1 is a diagram of an amplifier circuit 100 in an embodiment. The amplifier circuit 100 may include an input terminal NIN, an output terminal NOUT, transistors T1, T2, T3, a voltage tracking circuit C1, and a stacking circuit C12. The input terminal NIN may be used to receive an input signal SIN. The output terminal NOUT may be used to output the amplified input signal SIN, i.e., the signal SOUT. In FIG. 1, the input signal SIN may be a radio frequency (RF) signal, and the signal SOUT may be the amplified radio frequency signal. The transistors mentioned herein may be, but are not limited to, field-effect transistors, with their control terminals being gate terminals, and the first and second terminals being drain terminals and source terminals, respectively.

The transistor T1 may include a first terminal, a second terminal, and a control terminal, where the first terminal can receive a reference current IREF1, and the second terminal can be coupled to a bias terminal VR1.

The transistor T2 and a stacked circuit C12 may form an amplifier A1, which can amplify the input signal SIN to generate the signal SOUT.

The transistor T2 may include a first terminal, a second terminal, and a control terminal, where the first terminal can receive a reference current IREF2, the second terminal can be coupled to the bias terminal VR1, and the control terminal can be coupled to the input terminal NIN and the control terminal of the transistor T1.

The transistor T3 may include a first terminal, a second terminal, and a control terminal, where the first terminal can receive a reference current IREF3, and the second terminal can be coupled to the bias terminal VR1.

The voltage tracking circuit C1 can include input terminals N11, N12, N13, and an output terminal NO. The input terminal N11 can be coupled to the first terminal of transistor T1, the input terminal N12 can be coupled to the first terminal of transistor T2, the input terminal N13 can be coupled to the first terminal of transistor T3, and the output terminal NO can be coupled to the control terminal of transistor T1. In an embodiment, the input terminal N11 can be directly coupled to the first terminal of transistor T1, the input terminal N12 can be directly coupled to the first terminal of transistor T2, the input terminal N13 can be directly coupled to the first terminal of transistor T3, and the output terminal NO can be directly coupled to the control terminal of transistor T1.

The voltage tracking circuit C1 can be used to regulate a voltage VD1 at the first terminal of transistor T1 and a voltage VD4 at the first terminal of transistor T3 to be substantially equal during an initial state, and to regulate the voltage VD1 at the first terminal of transistor T1 and a voltage VD2 at the first terminal of transistor T2 to be substantially equal after a predetermined time has elapsed. In an embodiment, a voltage difference between the voltage VD1 at the first terminal of transistor T1 and the voltage VD4 at the first terminal of transistor T3 or the voltage VD2 at the first terminal of transistor T2 can be less than 3%.

For example, if the bias terminal VR1 is the ground terminal and has a ground voltage, then the voltage VD1 can be the drain-source voltage (commonly referred to as VDS) of the transistor T1, the voltage VD2 can be the drain-source voltage of the transistor T2, and the voltage VD4 can be the drain-source voltage of the transistor T3. However, embodiments are not limited thereto, and the voltage of the bias terminal VR1 can be adjusted as needed.

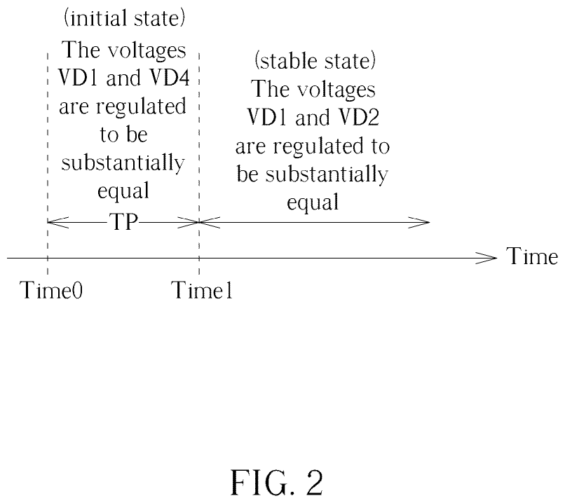

FIG. 2 is an operational diagram of the amplifier circuits 100 in FIG. 1 and FIG. 3 to FIG. 10. The horizontal axis of FIG. 2 can be a time axis. Taking FIG. 1 as an example, the amplifier circuit 100 can start operating at a time Time0. From a time Time0 to a time Time1, the amplifier circuit 100 can be in the initial state, and the duration of the initial state can be a predetermined time TP. In the initial state, the voltage tracking circuit C1 can regulate and maintain the voltage VD1 and the voltage VD4 to be substantially equal.

After the time Time1, the initial state ends, and the operation can enter a stable state. In the stable state, the voltage tracking circuit C1 can regulate and maintain the voltage VD1 and the voltage VD2 to be substantially equal.

In FIG. 2, the predetermined time TP can be between 0 and 2 microseconds (usec). In FIG. 1 and FIG. 2, for example, the transistor T2 can be part of an amplifier (for example, but not limited to, a power amplifier or a low-noise amplifier). In the initial state, the voltage tracking circuit C1 can regulate the voltage VD1 and the voltage VD4 to be substantially equal, which can avoid undesired oscillation problems caused by the voltage VD1 tracking the voltage VD2.

In the stable state, the voltage tracking circuit C1 can regulate the voltage VD1 and the voltage VD2 to be substantially equal, stabilizing the currents provided by the current mirror structure formed by the transistors T1 and T2. For example, the reference current IREF2 can be ensured to be an integer multiple of the reference current IREF1, allowing the amplifier to operate normally.

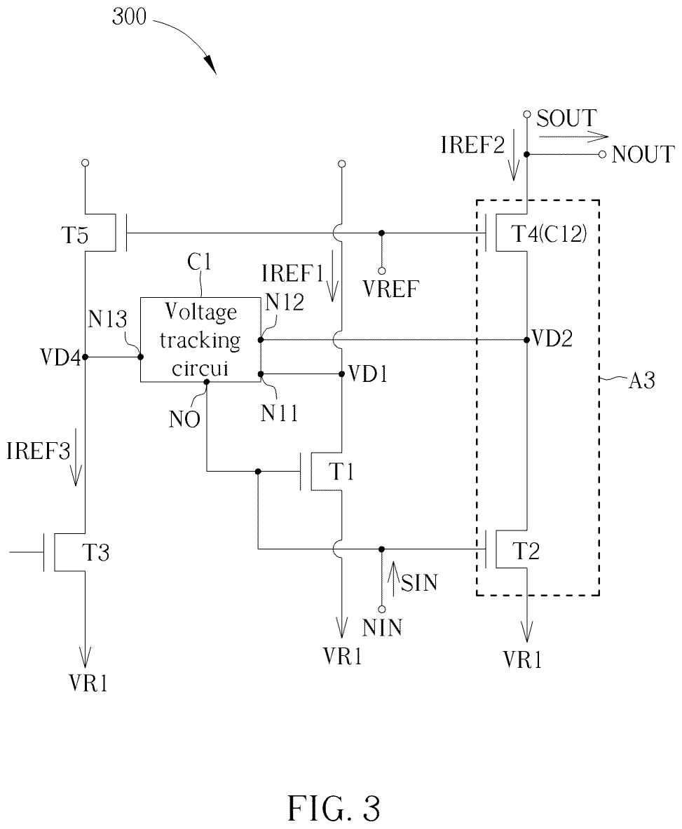

FIG. 3 shows a diagram of an amplifier circuit 300 according to another embodiment. The similarities between the amplifier circuit 300 and the amplifier circuit 100 will not be reiterated. As shown in FIG. 3, the stacking circuit C12 in FIG. 1 can include a transistor T4. The transistor T4 and the transistor T2 can form an amplifier A3. The transistor T4 can include a first terminal, a second terminal, and a control terminal, where the first terminal can be coupled to the output terminal NOUT, the second terminal can be coupled to the first terminal of the transistor T2, and the control terminal can be coupled to a reference voltage terminal VREF to receive a predetermined bias voltage.

The amplifier circuit 300 can also include a transistor T5. The transistor T5 can include a first terminal, a second terminal, and a control terminal, where the second terminal can be coupled to the first terminal of the transistor T3, and the control terminal can be coupled to the reference voltage terminal VREF and the control terminal of the transistor T4.

In FIG. 3, the transistor T4 and the transistor T5 can be corresponding to the same width-to-length ratio (W/L ratio). The size of the transistor T4 can be an integer multiple of the size of the transistor T5. The transistor T4 and the transistor T5 can form a current mirror structure. In the initial state of FIG. 2, when the voltage tracking circuit C1 regulates the voltage VD1 and the voltage VD4 to be substantially equal, the voltage VD2 can be regulated to be substantially equal to the voltage VD4 through mirroring, so that the voltage VD2 is regulated to be substantially equal to the voltage VD1, which is indirect voltage tracking operation.

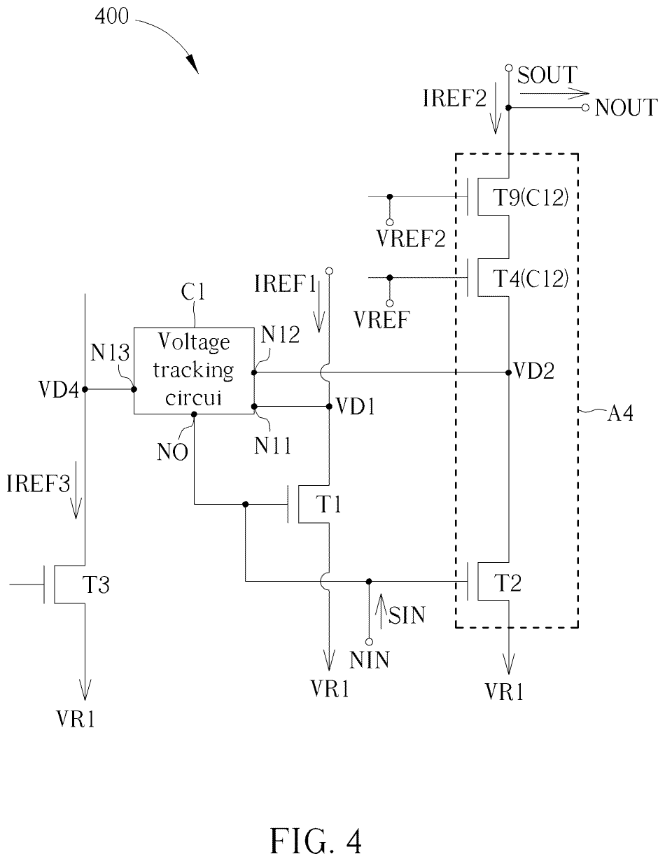

FIG. 4 shows a diagram of an amplifier circuit 400 according to another embodiment. The similarities between the amplifier circuit 400 and the amplifier circuit 100 will not be reiterated. The amplifier circuit 400 can include the transistor T2, the transistor T4, and a transistor T9. The transistor T4 can include a first terminal, a second terminal, and a control terminal, where the second terminal can be coupled to the first terminal of the transistor T2, and the control terminal can be coupled to the reference voltage terminal VREF to receive a predetermined bias voltage. The transistor T9 can include a first terminal, a second terminal, and a control terminal, where the first terminal can be coupled to the output terminal NOUT, the second terminal can be coupled to the first terminal of the transistor T4, and the control terminal can be coupled to the reference voltage terminal VREF2 to receive a predetermined bias voltage. In FIG. 4, the transistor T9, the transistor T4, and the transistor T2 can form an amplifier A4, such as a power amplifier or a low-noise amplifier.

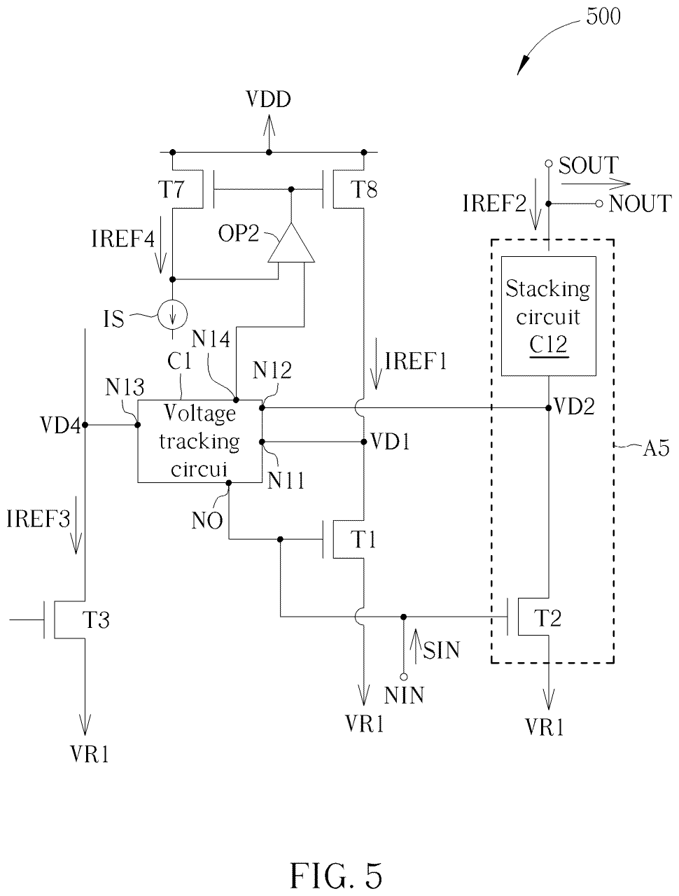

FIG. 5 shows a diagram of an amplifier circuit 500 according to another embodiment. The similarities between the amplifier circuit 500 and the amplifier circuits 100 and 300 will not be reiterated. In the amplifier circuit 500, the transistor T2 and the cascode circuit C12 can form an amplifier A5. The amplifier circuit 500 can also include a transistor T7 and a transistor T8. The transistor T7 can include a first terminal, a second terminal, and a control terminal, where the second terminal can be used to output a reference current IREF4. For example, the second terminal of the transistor T7 can be coupled to a current source IS to provide the reference current IREF4. The transistor T8 can include a first terminal, a second terminal, and a control terminal, where the first terminal can be coupled to the first terminal of the transistor T7, the second terminal can be coupled to the first terminal of the transistor T1, and the control terminal can be coupled to the control terminal of the transistor T7. The first terminal of the transistor T8 and the first terminal of the transistor T7 can be respectively coupled to a reference voltage source VDD. The transistor T7 and the transistor T8 can form a current mirror, which can generate the reference current IREF1 based on the reference current IREF4.

As shown in FIG. 5, the voltage tracking circuit C1 can also include an input terminal N14. The amplifier circuit 500 can also include an operational amplifier OP2, which can include a first terminal, a second terminal, and an output terminal. The first terminal of the operational amplifier OP2 can be coupled to the second terminal of the transistor T7. The second terminal of the operational amplifier OP2 can be coupled to the input terminal N14 of the voltage tracking circuit C1. The output terminal of the operational amplifier OP2 can be coupled to the control terminals of the transistor T7 and the transistor T8. The voltage tracking circuit C1 can be controlled to selectively electrically connect the input terminal N14 to the input terminal N12 or the input terminal N13.

The first terminal of the operational amplifier OP2 can be, but is not limited to, a negative input terminal, and the second terminal of the operational amplifier OP2 can be, but is not limited to, a positive input terminal. In FIG. 5, the structure formed by the transistor T7, the transistor T8, and the operational amplifier OP2 can provide the reference current IREF1.

In FIG. 5, the transistor T7 and the transistor T8 can be corresponding to the same width-to-length ratio (W/L ratio). The size of the transistor T8 can be an integer multiple of the size of the transistor T7, where the size can be defined using the gate width, width-to-length ratio, and/or the number of fingers of the transistor.

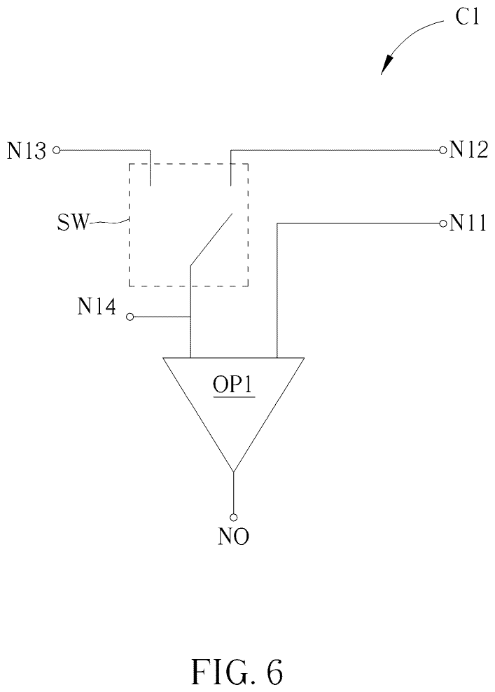

FIG. 6 shows a diagram of the voltage tracking circuit C1 in FIG. 1 and FIG. 3 to FIG. 5. The voltage tracking circuit C1 can include an operational amplifier OP1 and a switch circuit SW. The operational amplifier OP1 can include a first terminal, a second terminal, and an output terminal, where the first terminal is coupled to the input terminal N11 of the voltage tracking circuit C1, the second terminal is coupled to the input terminal N14 of the voltage tracking circuit C1, and the output terminal is coupled to the output terminal NO of the voltage tracking circuit C1. The switch circuit SW can be used to couple the second terminal of the operational amplifier OP1 to the input terminal N12 or the input terminal N13 of the voltage tracking circuit C1, to control the second terminal of the operational amplifier OP1 to be coupled to the first terminal of the transistor T2 or the first terminal of the transistor T3. In this embodiment, the operational amplifier OP1 can regulate the voltages at the first terminal and the second terminal of the operational amplifier OP1 to be substantially equal. Hence, the voltage at the input terminal N11 can be substantially equal to the voltage at the input terminal N13 or the input terminal N12.

In an embodiment, the first terminal of the operational amplifier OP1 can be, but is not limited to, a negative input terminal, and the second terminal of the operational amplifier OP1 can be, but is not limited to, the positive input terminal. In an embodiment, the first terminal of the operational amplifier OP1 can be directly coupled to the input terminal of the switch circuit SW, and the two output terminals of the switch circuit SW are directly coupled to the input terminals N12 and N13.

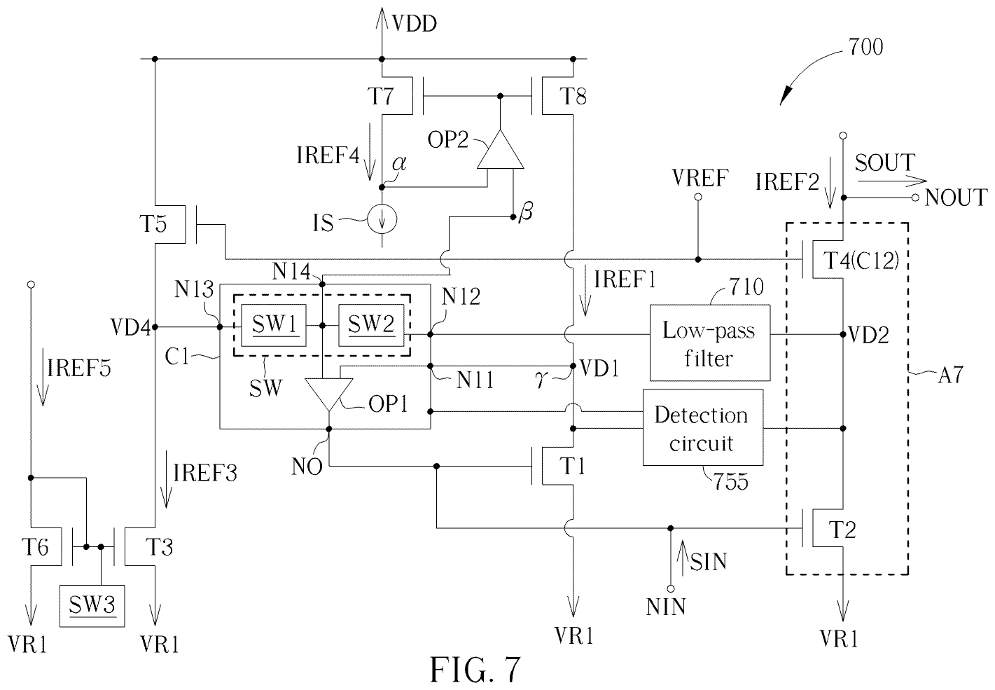

FIG. 7 shows a diagram of an amplifier circuit 700 according to another embodiment. As shown in FIG. 7, the switch circuit SW of the voltage tracking circuit C1 can include a first switch SW1 and a second switch SW2. The first switch SW1 can be coupled between the input terminal N13 of the voltage tracking circuit C1 and the second terminal of the operational amplifier OP1 (namely, the input terminal N14). The second switch SW2 can be coupled between the input terminal N12 of the voltage tracking circuit C1 and the second terminal of the operational amplifier OP1 (namely, the input terminal N14). The node between the first switch SW1 and the second switch SW2 can be coupled to the input terminal N14 of the voltage tracking circuit C1 described in FIG. 5. Therefore, the first switch SW1 can be coupled to the input terminal N14 of the voltage tracking circuit C1, the second terminal of the operational amplifier OP1, and the first terminal of the transistor T3. The second switch SW2 can be coupled to the input terminal N14 of the voltage tracking circuit C1, the second terminal of the operational amplifier OP1, and the first terminal of the transistor T2.

When one of the first switch SW1 and the second switch SW2 is turned on, the other can be turned off, as described below.

As shown in FIG. 2 and FIG. 7, in the initial state (e.g., between the time Time0 and the time Time1 in FIG. 2), the first switch SW1 can be turned on, and the second switch SW2 can be turned off, so that the voltage VD1 and the voltage VD4 can be substantially equal. At this time, through the mirroring of transistor T4 and transistor T5, the voltage VD2 can be regulated to be substantially equal to the voltage VD1, so that the current IREF2 can be a predetermined multiple of the current IREF1. Since the second switch SW2 is turned off at this stage, unexpected oscillation problems caused by the circuit loop are avoided.

As shown in FIG. 2 and FIG. 7, in the stable state (e.g., after the time Time1 in FIG. 2), the first switch SW1 can be turned off, and the second switch SW2 can be turned on. Hence, the voltage VD1 and the voltage VD2 can be substantially equal, and the current IREF2 can be a predetermined multiple of the current IREF1. Since the circuit operation is stable at this stage, unexpected oscillation problems caused by the circuit loop are avoided.

As shown in FIG. 7, the amplifier circuit 700 can optionally include a low-pass filter 710. The low-pass filter 710 can include a first terminal and a second terminal, where the first terminal can be coupled to the input terminal N12 of the voltage tracking circuit C1, and the second terminal can be coupled to the first terminal of the transistor T2. The low-pass filter 710 can reduce the interference of the signal SOUT (e.g., radio frequency signal) to the circuit.

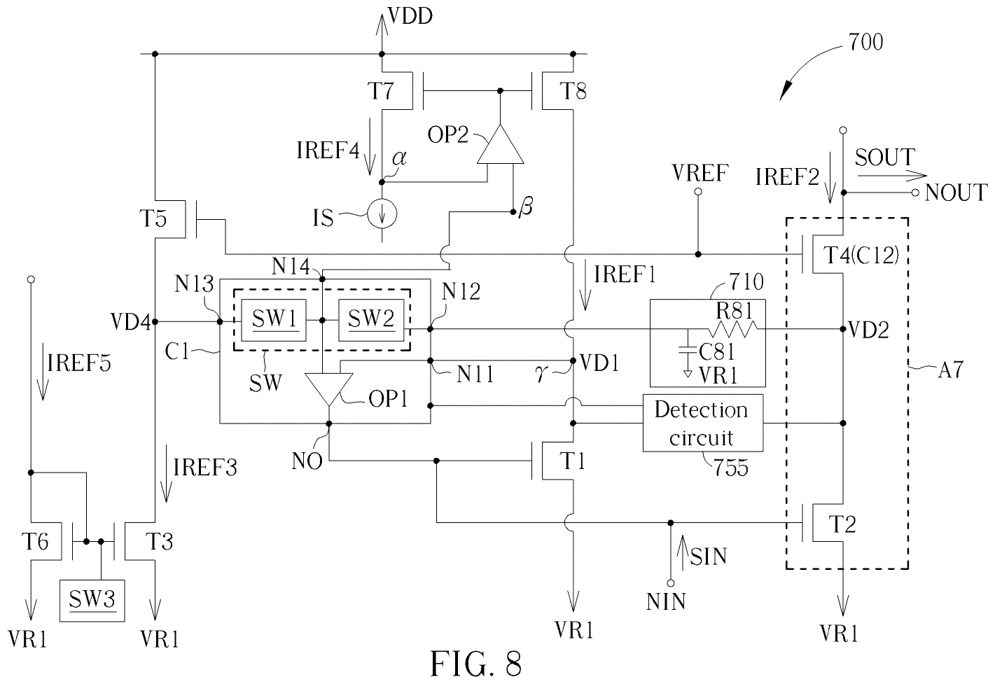

FIG. 8 shows a diagram of the amplifier circuit 700 of FIG. 7 according to another embodiment. As shown in FIG. 8, the low-pass filter 710 can include, but is not limited to, a capacitor C81 and a resistor R81. The capacitor C81 can be coupled between the input terminal N12 of the voltage tracking circuit C1 and the bias terminal VR1. The resistor R81 can be coupled between the input terminal N12 of the voltage tracking circuit C1 and the first terminal of the transistor T2.

As shown in FIG. 7 and FIG. 8, the amplifier circuit 700 can further include a transistor T6. The transistor T6 can include a first terminal, a second terminal, and a control terminal, where the first terminal can receive a reference current IREF5, the second terminal may be coupled to the bias terminal VR1, and the control terminal can be coupled to the control terminal of the transistor T3 and the first terminal of the transistor T6. The transistor T6 and the transistor T3 can form a current mirror to provide a reference current IREF3 based on the reference current IREF5. In an embodiment, the transistor T6, the transistor T4, and the transistor T1 can be corresponding to the same width-to-length ratio.

In FIG. 7 and FIG. 8, the amplifier A7 can include the transistor T4 and the transistor T2, but this is only an example. If, as shown in FIG. 4, the amplifier (e.g., A4) includes the transistor T9, the transistor T4, and the transistor T2, this is also within the scope of embodiments. When the amplifier includes the transistor T9, the transistor T4, and the transistor T2, the control terminal of the transistor T4 can be coupled to the control terminal of the transistor T5 to perform mirroring operation and indirect voltage tracking operation, so that in an unstable state, the voltage VD2 can be regulated to be substantially equal to the voltage VD4.

As shown in FIG. 7 and FIG. 8, the voltage at a node α can track the voltage at a node β through the operational amplifier OP2, and the voltage at a node γ can track the voltage at the node β through the operational amplifier OP1. Therefore, the ratio of the reference current IREF1 to the reference current IREF4 is accurate.

In FIG. 1 and FIG. 3 to FIG. 8, according to an embodiment, the transistor T1 and the transistor T2 can be corresponding to the same width-to-length ratio. The size of the transistor T2 can be substantially M times the size of the transistor T1, where M is a positive integer or the number of fingers. For example, in semiconductor layout and semiconductor processes, if the transistor T1 is an element, M transistors T1 can be used to form the transistor T2. In an embodiment, the transistor T1 and the transistor T3 can be corresponding to the same width-to-length ratio.

As shown in FIG. 7 and FIG. 8, the amplifier circuit 700 can further include a switch SW3. The switch SW3 can be coupled to the transistor T3 to turn on and off the transistor T3.

In FIG. 7 and FIG. 8, the switch SW3 can be coupled to the control terminal of the transistor T3. However, this is only an example, and embodiments are not limited thereto. The switch SW3 can be selectively coupled to at least one of the first terminal, the second terminal, and the control terminal of the transistor T3 to turn the transistor T3 on and off.

The control of the transistor T3 can be as described below. When the amplifier circuit 700 is controlled to regulate the voltage VD1 at the first terminal of the transistor T1 to be substantially equal to the voltage VD4 at the first terminal of the transistor T3 (e.g., in the initial state of FIG. 2), the switch SW3 can turn on the transistor T3.

After the predetermined time TP in FIG. 2 (i.e., after the time Time1 of FIG. 2, and in the stable state), the amplifier circuit 700 can be controlled to regulate the voltage VD1 at the first terminal of the transistor T1 to be substantially equal to the voltage VD2 at the first terminal of the transistor T2, and the switch SW3 can turn off the transistor T3.

In FIG. 1 to FIG. 5, FIG. 7, and FIG. 8, the input terminal N13 of the voltage tracking circuit C1 can regulate the voltage VD1 at the first terminal of the transistor T1 and the voltage VD4 at the first terminal of the transistor T3 to be substantially equal in an unstable state. The aforementioned unstable state can be, for example, the initial state of FIG. 2, where the amplifier circuit has just started operating and is not yet stable. Alternatively, for example, the unstable state can be caused by factors such as main power switching, reference voltage switching, excessive changes in the input signal SIN, and/or sudden temperature changes.

As shown in FIG. 7, the amplifier circuit 700 can optionally include a detection circuit 755. The detection circuit 755 can be used to detect the voltage VD1 at the first terminal of the transistor T1 and the voltage VD2 at the first terminal of the transistor T2 to determine the length of the predetermined time TP in FIG. 2. In other words, the detection circuit 755 can determine the duration of the initial state in FIG. 2. According to embodiments, the detection circuit 755 can be coupled to the voltage tracking circuit C1 or notify the voltage tracking circuit C1 of the end of the predetermined time TP through a control circuit.

In response to that the voltage VD1 at the first terminal of the transistor T1 and the voltage VD2 at the first terminal of the transistor T2 change from unequal to substantially equal, the detection circuit 755 can end the predetermined time TP, and the voltage tracking circuit C1 can regulate the voltage VD1 and the voltage VD2 to be substantially equal to maintain the predetermined ratio between the reference current IREF2 and the reference current IREF1.

The transistor T3 and the transistor T6 can form a current mirror structure to generate a voltage for the transistor T5, so that the electrical state of the transistor T5 can be mirrored to the transistor T4 to generate the same current. Since the reference voltage terminal VREF only provides a voltage to the control terminal of the transistor T4 (e.g., the gate terminal of the transistor T4), it is still necessary to define the voltage VD2, which is the voltage at the second terminal of the transistor T4 (e.g., the source voltage), to generate the voltage difference between the control terminal and the second terminal of the transistor T4 (e.g., the gate-source voltage of the transistor T4) to drive the transistor T4.

According to embodiments, the channel length of the transistor T3 can be greater than the channel length of the transistor T2. When the transistor T2 is part of an amplifier (e.g., low noise amplifier, LNA), to increase the gain of the amplifier, the transistors of the amplifier can have a smaller channel length, which is smaller than that of the bias transistors. When the channel length is smaller, it will lead to adverse effects, resulting in poorer mirroring effects of the current mirror formed by the transistor T1 and the transistor T2. Therefore, the voltage tracking circuit C1 can be used for voltage tracking. For example, the operational amplifier OP1 shown in FIG. 6 and FIG. 7 can be used for voltage tracking. To reduce the use of additional components, the transistors T3 and T6 can have a larger channel length compared to the transistor T2 to reduce the adverse effects caused by the smaller channel length and improve the mirroring effect.

When the operation of the overall circuit is stable, the voltage tracking circuit C1 can be used for direct tracking to regulate the voltage VD1 at the first terminal of the transistor T1 and the voltage VD2 at the first terminal of the transistor T2 to be substantially equal. At this time, indirect voltage tracking operation through the transistor T3 is no longer necessary. Therefore, when the voltage VD1 is stable and accurate, the transistor T3 and the transistor T6 can be turned off.

FIG. 8 is a flowchart of a bias current method 800 for stabilizing the amplifier circuits of FIG. 1 to FIG. 7 according to an embodiment. The bias current method 800 can include the following steps.

Step 810: utilize the transistor T1 to receive the reference current IREF1;

Step 820: utilize the transistor T2 to receive the reference current IREF2, where the control terminal of the transistor T2 can be coupled to the input terminal NIN and the control terminal of the transistor T1, and the second terminal of the transistor T1 and the second terminal of the transistor T2 can be coupled to the bias terminal VR1;

Step 830: utilize the transistor T3 to receive the reference current IREF3;

Step 840: utilize the output terminal NO of the voltage tracking circuit C1 coupled to the control terminal of the transistor T1;

Step 850a: utilize the voltage tracking circuit C1 coupled to the first terminal of the transistor T1, where the voltage tracking circuit C1 can regulate the voltage VD1 at the first terminal of the transistor T1 and the voltage VD4 at the first terminal of the transistor T3 to be substantially equal in the initial state;

Step 850b: after entering the stable state, regulate the voltage VD1 at the first terminal of the transistor T1 and the voltage VD2 at the first terminal of the transistor T2 to be substantially equal; and

Step 850c: after entering the unstable state, regulate the voltage VD1 at the first terminal of the transistor T1 and the voltage VD4 at the first terminal of the transistor T3 to be substantially equal.

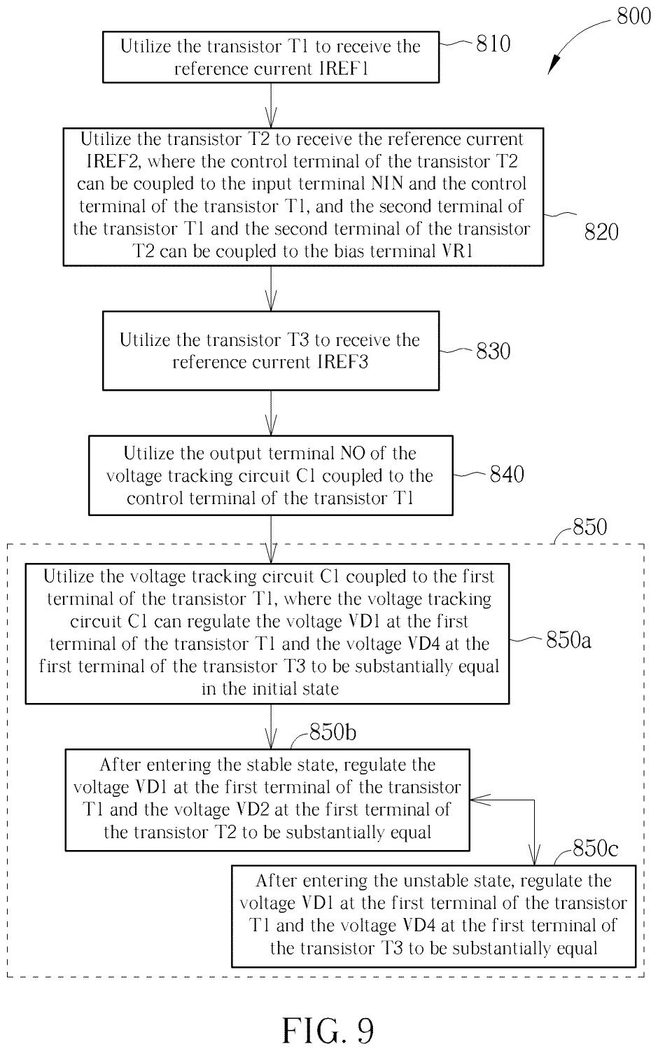

In FIG. 9, the sequence of steps 810 to 850 is only an example. Reasonable adjustments to the sequence of the steps are still within the scope of embodiments.

As shown in FIG. 1 to FIG. 9, before the amplifier circuit is stable (e.g., in the initial state of FIG. 2), the voltage tracking circuit C1 can regulate the voltage VD1 and the voltage VD4 to make them substantially equal. Then, through the mirroring operation (e.g., through the transistor T5 and the transistor T4 in FIG. 7), the voltage VD4 and the voltage VD2 can be approximately equal. Through this indirect voltage tracking operation, the current of the amplifier (e.g., the reference current IREF2) can be approximately equal to the expected current value, and unexpected oscillations can be avoided. After the amplifier circuit is stable (e.g., in the stable state of FIG. 2), the voltage tracking circuit C1 can regulate the voltage VD1 and the voltage VD2 to be approximately equal. Through this direct voltage tracking operation, the current of the amplifier (e.g., amplifiers A1, A3, A4, A5, and A7) can be ensured to have the expected current value.

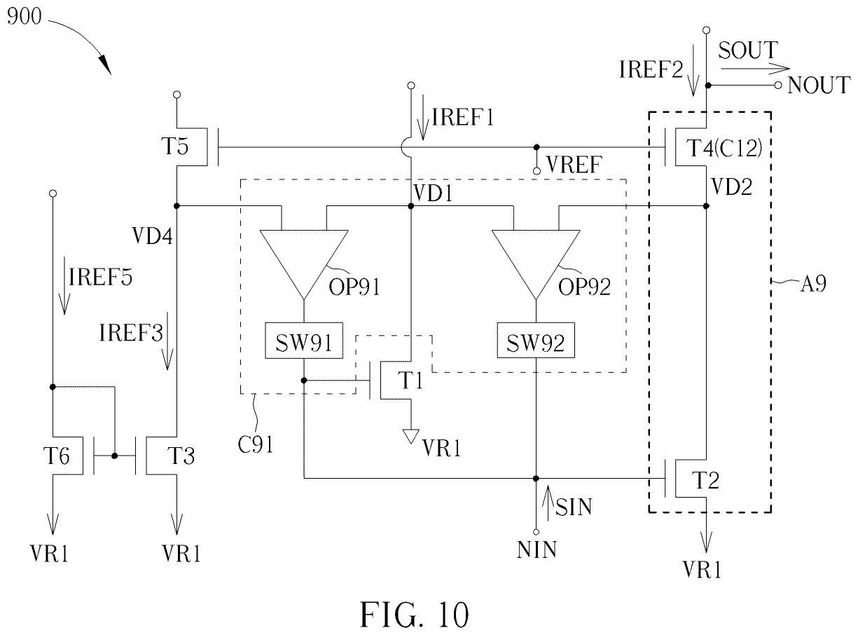

FIG. 10 shows a diagram of an amplifier circuit 900 according to another embodiment. Similarities between amplifier circuit 900 and amplifier circuit 700 are not reiterated. The amplifier circuit 900 can include a transistor T1, a transistor T2, a transistor T4, a transistor T3, a transistor T5, a transistor T6, a voltage tracking circuit C91, where the voltage tracking circuit C91 can include a first operational amplifier OP91, a second operational amplifier OP92, a first switch SW91, and a second switch SW92. The function of the voltage tracking circuit C91 can be similar to the aforementioned voltage tracking circuit C1.

When the operation of the amplifier circuit 900 is not yet stable (for example, the initial state of FIG. 2), the first switch SW91 can be turned on, and the second switch SW92 can be turned off, so that the voltage VD1 and the voltage VD4 can be substantially equal, and through the mirror operation of transistor T5 and transistor T4, the voltage VD2 can be approximately equal to the voltage VD1 through indirect voltage tracking operation.

When the operation of the amplifier circuit 900 is stable (for example, in the stable state of FIG. 2), the first switch SW91 can be turned off, and the second switch SW92 can be turned on, so that the voltage VD1 and the voltage VD2 can be substantially equal through direct voltage tracking operation.

Through the above operation, it can be ensured that the reference current IREF2 is a predetermined multiple of the reference current IREF1. For example, transistor T2 and transistor T4 can be transistors of an amplifier A9 (for example, a power amplifier or a low-noise amplifier). When the reference current IREF2 has a stable current value, the performance of the amplifier A9 can be ensured.

In summary, utilizing the above-mentioned amplifier circuits 100, 300, 400, 500, 700, and 900 and the bias current method 800, indirect voltage tracking operation can be performed in the unstable state of the amplifier circuit to avoid unexpected oscillations. In the stable state of the amplifier circuit, direct voltage tracking operation can be performed to further ensure the current value and performance of the amplifier. Hence, the amplifier circuit and bias current method provided by embodiments are beneficial for improving the control of the amplifier.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplifier circuit, comprising:
an input terminal configured to receive an input signal;
an output terminal configured to output an amplified input signal;
a first transistor, comprising:
a first terminal configured to receive a first reference current;
a second terminal coupled to a first bias terminal; and
a control terminal;
a second transistor, comprising:
a first terminal configured to receive a second reference current;
a second terminal coupled to the first bias terminal; and
a control terminal coupled to the input terminal and the control terminal of the first transistor;
a third transistor, comprising:
a first terminal configured to receive a third reference current;
a second terminal coupled to the first bias terminal; and
a control terminal; and
a voltage tracking circuit, comprising:
a first input terminal coupled to the first terminal of the first transistor;
a second input terminal coupled to the first terminal of the second transistor;
a third input terminal coupled to the first terminal of the third transistor; and
a first output terminal coupled to the control terminal of the first transistor;
wherein the voltage tracking circuit is configured to regulate voltages at the first terminal of the first transistor and the first terminal of the third transistor to be substantially equal during an initial state, and to regulate voltages at the first terminal of the first transistor and the first terminal of the second transistor to be substantially equal after a predetermined time has elapsed.

2. The amplifier circuit of claim 1, further comprising:
a fourth transistor comprising:
a first terminal coupled to the output terminal;
a second terminal coupled to the first terminal of the second transistor; and
a control terminal coupled to a reference voltage terminal.

3. The amplifier circuit of claim 2, further comprising:
a fifth transistor, comprising:
a first terminal;
a second terminal coupled to the first terminal of the third transistor; and
a control terminal coupled to the reference voltage terminal.

4. The amplifier circuit of claim 3, wherein the fourth transistor and the fifth transistor are corresponding to a same width-to-length ratio.

5. The amplifier circuit of claim 1, further comprising:
a fourth transistor comprising:
a first terminal;
a second terminal coupled to the first terminal of the second transistor; and
a control terminal coupled to a first reference voltage terminal;
a ninth transistor comprising:
a first terminal coupled to the output terminal;
a second terminal coupled to the first terminal of the fourth transistor; and
a control terminal coupled to a second reference voltage terminal.

6. The amplifier circuit of claim 1, further comprising:
a seventh transistor comprising:
a first terminal;
a second terminal configured to output a fourth reference current; and
a control terminal; and
an eighth transistor comprising:
a first terminal coupled to the first terminal of the seventh transistor;
a second terminal coupled to the first terminal of the first transistor; and
a control terminal coupled to the control terminal of the seventh transistor.

7. The amplifier circuit of claim 6, wherein:
the amplifier circuit further comprises a second operational amplifier, comprising:
a first terminal coupled to the second terminal of the seventh transistor;
a second terminal coupled to a fourth input terminal of the voltage tracking circuit; and
an output terminal coupled to the control terminal of the seventh transistor; and
the voltage tracking circuit further comprises:
the fourth input terminal; and
a first switch coupled between the fourth input terminal and the first terminal of the third transistor.

8. The amplifier circuit of claim 6, wherein the seventh transistor and the eighth transistor are corresponding to a same width-to-length ratio.

9. The amplifier circuit of claim 1, wherein the voltage tracking circuit further comprises:
a first operational amplifier comprising:
a first terminal coupled to the first input terminal of the voltage tracking circuit;
a second terminal; and
an output terminal coupled to the output terminal of the voltage tracking circuit; and
a switch circuit configured to couple the second terminal of the first operational amplifier to
the second input terminal or the third input terminal of the voltage tracking circuit, the switch circuit comprising:
a first terminal coupled to the second terminal of the first operational amplifier;
a second terminal coupled to the second input terminal of the voltage tracking circuit; and
a third terminal coupled to the third input terminal of the voltage tracking circuit.

10. The amplifier circuit of claim 9, wherein the switch circuit comprises:
a first switch coupled between the second terminal of the first operational amplifier and the first terminal of the third transistor; and
a second switch coupled between the second terminal of the first operational amplifier and the first terminal of the second transistor.

11. The amplifier circuit of claim 9, wherein the amplifier circuit further comprises:
a low-pass filter comprising:
a first terminal coupled to the second input terminal of the voltage tracking circuit; and
a second terminal coupled to the first terminal of the second transistor.

12. The amplifier circuit of claim 1, wherein:
the first transistor and the second transistor are corresponding to a same width-to-length ratio; and
a size of the second transistor is substantially M times a size of the first transistor, where M is a positive integer.

13. The amplifier circuit of claim 12, wherein:
the first transistor and the third transistor are corresponding to the same width-to-length ratio.

14. The amplifier circuit of claim 1, wherein the predetermined time is between 0 microseconds and 2 microseconds.

15. The amplifier circuit of claim 14, further comprising:
a third switch configured to turn on or turn off the third transistor,
wherein after the predetermined time has elapsed, the third switch turns off the third transistor.

16. The amplifier circuit of claim 15, wherein the third transistor is turned on in response to that voltages at the first terminal of the first transistor and the first terminal of the third transistor are regulated to be substantially equal.

17. The amplifier circuit of claim 1, wherein the third input terminal of the voltage tracking circuit is configured to regulate voltages at the first terminal of the first transistor and the first terminal of the third transistor to be substantially equal during an unstable state.

18. The amplifier circuit of claim 1, further comprising:
a detection circuit configured to detect voltages at the first terminal of the first transistor and the first terminal of the second transistor to determine a length of the predetermined time;
wherein in response to that the voltages at the first terminal of the first transistor and the first terminal of the second transistor change from unequal to substantially equal, the detection circuit ends the predetermined time, and the voltage tracking circuit regulates the voltages at the first terminal of the first transistor and the first terminal of the second transistor to be substantially equal.

19. A method for stabilizing a bias current of an amplifier circuit, the amplifier circuit comprising an input terminal for receiving an input signal and an output terminal for outputting an amplified input signal, the method comprising:
utilizing a first transistor to receive a first reference current;
utilizing a second transistor to receive a second reference current, wherein a control terminal of the second transistor is coupled to the input terminal and a control terminal of the first transistor, and the first transistor and the second transistor are coupled to a first bias terminal;
utilizing a third transistor to receive a third reference current;
utilizing a voltage tracking circuit coupled to a first terminal of the first transistor for regulating voltages at the first terminal of the first transistor and the first terminal of the third transistor to be substantially equal during an initial state, and regulating voltages at the first terminal of the first transistor and the first terminal of the second transistor to be substantially equal after a predetermined time has elapsed; and
utilizing a first output terminal of the voltage tracking circuit coupled to the control terminal of the first transistor.

20. The method for stabilizing the bias current of the amplifier circuit of claim 19, further comprising utilizing the voltage tracking circuit to regulate the voltages at the first terminal of the first transistor and the first terminal of the third transistor to be substantially equal during an unstable state.
